(19) United States
(12) Patent Application Publication
(10) Pub. No.: US 2025/0148274 A1
(43) Pub. Date: May 8, 2025

(54) Deep Neural Network Device Based on Dual Spin Orbit Torque (SOT) Devices

(71) Applicants: Western Digital Technologies, Inc., San Jose, CA (US); Tokyo Institute of Technology, Tokyo (JP)

(72) Inventors: Quang LE, San Jose, CA (US); Xiaoyong LIU, San Jose, CA (US); Brian R. YORK, San Jose, CA (US); Hisashi TAKANO, Fujisawa-shi (JP); Nam Hai PHAM, Tokyo (JP)

(73) Assignee: Western Digital Technologies, Inc., San Jose, CA (US)

(21) Appl. No.: 18/645,195

(22) Filed: Apr. 24, 2024

Related U.S. Application Data
(60) Provisional application No. 63/547,479, filed on Nov. 6, 2023.

(51) Int. Cl. G06N 3/063; H10N 50/20

(52) U.S. Cl. CPC G06N 3/063; H10N 50/20

(57) ABSTRACT

The present disclosure generally relates to a deep neural network (DNN) device utilizing spin orbital-spin orbital (SO-SO) devices. The SO-SO devices each includes two SOT layers, a first spin orbit torque (SOT1) layer, a second spin orbit torque (SOT2) layer, and a ferromagnetic layer disposed between the SOT1 and SOT2 layer. Each SO-SO device further comprises three terminals, one per each SOT layer, for in plane current flow to or from the respective SOT layer, and one for perpendicular current flow through multiple layers, or the overall stack, of the SO-SO device. The SO-SO device thus efficiently provides spin-to-charge and charge-to-spin mechanisms in the same device, and can be flexibility configured to perform various functions of a neural node of a DNN. These functions include storing programmed weights, multiplying inputs and weights and summing such multiplication results, and performing an activation function to determine a neural node output.

### CROSS-REFERENCE TO RELATED APPLICATIONS

This application claims benefit of U.S. provisional patent application Ser. No. 63/547,479, filed Nov. 6, 2023, which is herein incorporated by reference.

### BACKGROUND OF THE DISCLOSURE

### Field of the Disclosure

Embodiments of the present disclosure generally relate to a deep neural network (DNN) device utilizing spin orbital-spin orbital (SO-SO) logic.

### Description of the Related Art

Deep neural networks (DNNs) are a promising and quickly evolving area of technology utilized in artificial intelligence (AI). DNNs are composed of multiple layers (two or more) between the input and final output layers. DNNs transform data at each layer, creating a new representation of each layer output. The core feature of some DNNs involves matrix multiplication/summation followed by an active function (e.g., a non-linear transfer function). Many DNNs currently rely solely on a traditional computing architecture with discrete memory and processor components to perform both the matrix multiplication/summation and the activation function. Traditional computing architecture-based implementations of a DNN generally require more data movement between a main memory and a CPU/GPU, which is more power/memory consuming and low speed. Hardware compute-in-memory implementations of DNNs promise lower energy, non-linear, and higher density for AI applications. However, the current compute-in-memory hardware implementations of DNN are still limited.

Therefore, there is a need in the art for new hardware implementations for DNNs.

### SUMMARY OF THE DISCLOSURE

The present disclosure generally relates to a deep neural network (DNN) device utilizing spin orbital-spin orbital (SO-SO) devices. The SO-SO devices each includes two SOT layers, a first spin orbit torque (SOT1) layer, a second spin orbit torque (SOT2) layer, and a ferromagnetic layer disposed between the SOT1 and SOT2 layer. Each SO-SO device further comprises three terminals, one per each SOT layer, for in plane current flow to or from the respective SOT layer, and one for perpendicular current flow through multiple layers, or the overall stack, of the SO-SO device. The SO-SO device thus efficiently provides spin-to-charge and charge-to-spin mechanisms in the same device, and can be flexibility configured to perform various functions of a neural node of a DNN. These functions include storing programmed weights, multiplying inputs and weights and summing such multiplication results, and performing an activation function to determine a neural node output.

In one embodiment, a DNN device comprises one or more first devices configured to perform a first operation of a neural node of a deep neural network (DNN), the one or more first devices each comprising: a first spin orbit torque (SOT1) layer, a second spin orbit torque (SOT2) layer, a ferromagnetic layer disposed between the SOT1 and SOT2 layer, a first terminal coupled to the SOT1 layer, a second terminal coupled over the SOT2 layer, the second terminal being configured for an input current path that is perpendicular to a plane of the SOT2 layer, the input current path being configured to extend into the ferromagnetic layer, and a third terminal coupled to the SOT2 layer, the third terminal being configured for an output current path that is in plane of the SOT2 layer.

In another embodiment, a DNN device comprises a plurality of rows, a plurality of columns, a spin-orbit spin-orbit (SO-SO) device disposed at each cross-point between rows of the plurality of rows and columns of the plurality of columns configured to perform a first operation of a neural node of a deep neural network (DNN), each SO-SO device comprising: a first spin orbit torque (SOT1) layer, a second spin orbit torque (SOT2) layer, and a ferromagnetic layer disposed between the SOT1 and SOT2 layer, wherein a plurality of input currents are configured to be applied to each SO-SO device disposed in each row of the plurality of rows, and a plurality of output SO-SO devices disposed within each column configured to perform a second operation of a neural node of a DNN, each output SO-SO device comprising: a SOT1 layer, a SOT2 layer, and a ferromagnetic layer disposed between the SOT1 and SOT2 layer, wherein an output current of each SO-SO device disposed in each column of the plurality of columns is configured to be input as an input current into the plurality of output SO-SO devices.

In yet another embodiment, a DNN device comprises a first layer of a plurality of first spin orbit torque (SOT) devices configured to perform a first operation of a neural node of a deep neural network (DNN), each first SOT device comprising: a first spin orbit torque layer, a second spin orbit torque layer coupled to a first output terminal, and a ferromagnetic layer disposed between the first and second spin orbit torque layers, wherein each first SOT device is individually configured to generate, via the second SOT layer, an output current responsive to a direction of the magnetization of the ferromagnetic layer and an input current, the output current being output through the first output terminal of each first SOT device, and a second layer of a plurality of second SOT devices configured to perform a second operation of a neural node of a DNN, each second SOT device comprising: a first spin orbit torque layer coupled to a first input terminal, a second spin orbit torque layer, and a ferromagnetic layer disposed between the first and second spin orbit torque layers, wherein the output current of each first SOT device is configured to be input into the first input terminal of each second SOT device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a schematic of a simplified deep neural network (DNN), according to one embodiment.

FIG. 1B illustrates an example embodiment of a neural node, according to one embodiment.

FIG. 2 illustrates a spin orbital-spin orbital (SO-SO) element, according to one embodiment.

FIG. 3 illustrates an example embodiment of SO-SO devices in neural network configurations.

FIG. 4 illustrates a cross-bar array for a DNN, according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to a deep neural network (DNN) device utilizing spin orbital-spin orbital (SO-SO) devices. The SO-SO devices each includes two SOT layers, a first spin orbit torque (SOT1) layer, a second spin orbit torque (SOT2) layer, and a ferromagnetic layer disposed between the SOT1 and SOT2 layer. Each SO-SO device further comprises three terminals, one per each SOT layer, for in plane current flow to or from the respective SOT layer, and one for perpendicular current flow through multiple layers, or the overall stack, of the SO-SO device. The SO-SO device thus efficiently provides spin-to-charge and charge-to-spin mechanisms in the same device, and can be flexibility configured to perform various functions of a neural node of a DNN. These functions include storing programmed weights, multiplying inputs and weights and summing such multiplication results, and performing an activation function to determine a neural node output.

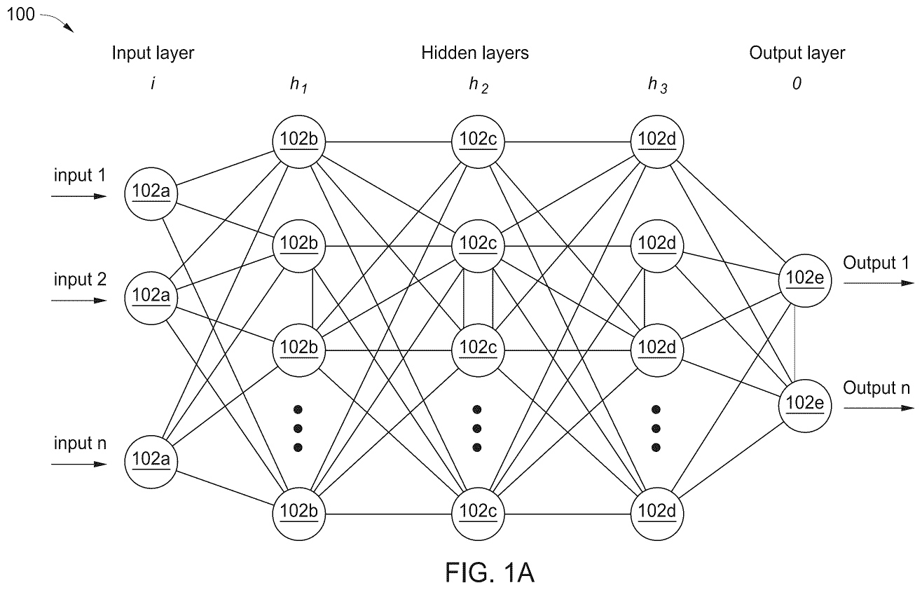

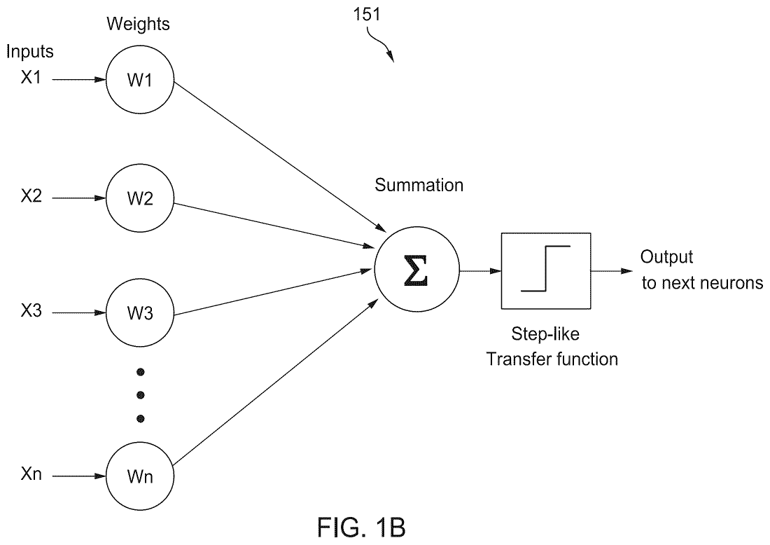

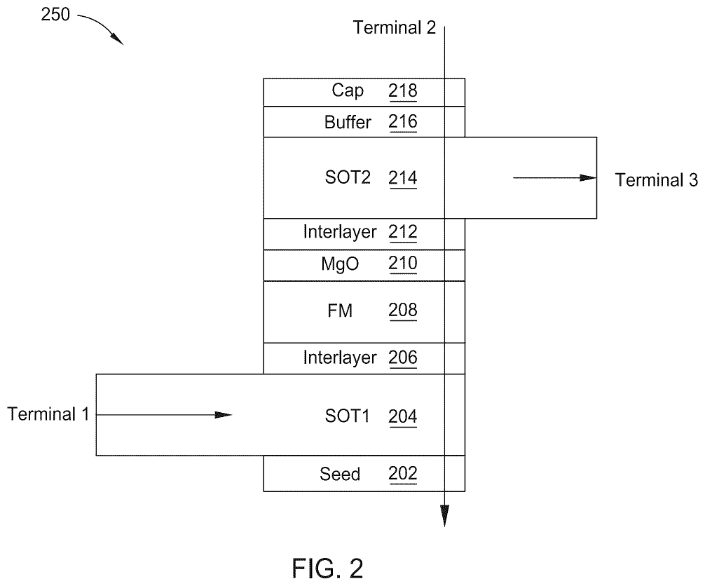

FIG. 1A illustrates a schematic of a simplified deep neural network (DNN) 100, according to one embodiment. The DNN 100 comprises a plurality of neural nodes 102a, 102b, 102c, 102d, 102e (collectively referred to herein as neural nodes 102). In some embodiments, each neural node 102 can be implemented as a plurality of spin orbital-spin orbital (SO-SO) devices (described below in FIG. 2), where each SO-SO device comprises a three-terminal device, comprising a control or weight, an input, and an output, as discussed further below in FIGS. 2-4). An input current (input 1, input 2, input n) is applied to a first input layer (i) of neural nodes 102a and multiplied by the control or weight. The output of each neural node 102a of the input layer is then output to each neural node 102b in a first hidden layer (h1) of the DNN 100 as the input for each neural node 102b, where each received input at each neural node 102b is then multiplied by a respective weight for the respective input of each neural node 102b. A weight may conceptually represent a strength of the connection between a neural node in one layer (e.g., neural node 102a) and another neural node in the next layer (e.g., neural node 102b). The results of the multiplications are collectively summed together and sent to a non-linear activation function (not shown here), such as a step or a rectified linear unit (ReLU) function, which determines the final output for that neural node 102b. This multiplication, summation and activation function sequence of processes is then repeated in the various layers h2, h3, etc. throughout the DNN. While three hidden layers are shown, the DNN 100 may comprise any number of hidden layers. Finally, the output of the last hidden layer (here, the third hidden layer) is output to output neural nodes 102e of an output layer (o) as a final result.

FIG. 1B illustrates an example embodiment a neural node 151. For example, FIG. 1B may show one neural node of each layer (i, h1, h2, h3, o) of the DNN 100 of FIG. 1A. A neural node 151 is shown, and in one embodiment is implemented as a plurality of SO-SO devices, described below in FIG. 2. The neural node 151 takes a summation of input X₁ . . . . Xₙ multiplied by weights W₁ . . . Wₙ. This is also referred to as a multiply-accumulate (MAC) operation. Besides this MAC operation, the node feeds the MAC output to an activation function to provide a final output of the node. The activation function, which may be a step-like function or a ReLU activation function, will generate an output to node(s) in the next layer(s) of the neural network. The output in some embodiments is dependent on whether the result of the MAC operation meets a threshold in the step-like function (activated vs. not activated). The MAC operation and the activation function constitute two core functions of the neural node.

FIG. 2 illustrates a spin orbital-spin orbital (SO-SO) device 250, according to one embodiment. The various layers of the SO-SO device 250 are not drawn to scale, and are intended for illustrative purposes only. The SO-SO devices may be referred to herein as SOT devices. A plurality of SO-SO devices 250 may be configured to function as a neural node 102 of FIG. 1A. Thus, a collection of SO-SO devices may be configured to represent a layer (i, h1, h2, h3, o) of the DNN of FIG. 1A.

In some embodiments, the SO-SO device 250 comprises a seed layer 202, a first spin orbit torque (SOT) layer 204 (SOT1) disposed on the seed layer 202, a first interlayer 206 disposed on the first SOT layer 204, a ferromagnetic (FM) layer 208 disposed on the first interlayer 206, an oxide layer 210 (e.g., an MgO layer) disposed on the FM layer 208, a second interlayer 212 disposed on the oxide layer 210, a second SOT layer 214 (SOT2) disposed on the second interlayer 212, a buffer layer 216 disposed on the second SOT layer 214, and a cap layer 218 disposed on the buffer layer 216. The oxide layer 210 may be referred to herein as an MgO layer 210. However, the oxide layer 210 may comprise other materials, such as oxides of Ti, V, Cr, Mn, Fe, Ni, Zr, nitrides of Sc, Ti, V, Cr, Fe, Zr, Ta, Hf, W, carbides of Sc, Ti, V, Zr, Ta, Hf, W, and alloy combinations thereof.

The seed layer 202, interlayers 206 and 212, oxide layer 210 and cap layer 218 are optional in some embodiments. For example, in some embodiments, the SO-SO device 250 comprises only the first SOT layer 204, the second SOT layer 214, and the FM layer 208 therebetween. In other embodiments, the SO-SO device 250 comprises only the first SOT layer 204, the second SOT layer 214, the FM layer 208, and oxide layer 210. The oxide layer 210 enhances the output of the SO-SO device 250 and further prevents backflow of pure spin current due to the output current. These layers may also be tuned to optimize the characteristics of the SOT layers 204, 214 (e.g., to increase the effective spin Hall angle which would improve the efficiency of the overall device).

The seed layer 202 may be a multilayer structure comprising layer combinations of: (1) one or more amorphous conditioning layers, such as NiTa, NiW, NiFeTa, NiFeW, etc.; (2) an RuAl texturing layer; (3) an MgO layer; and (4) NiₓRu₍₁₋ₓ₎Al (where x is from zero to 1) alloys, any crystalline or nanocrystalline, nonmagnetic element, or an alloy material with an equivalent BCC or B2 lattice parameter in the range of 2.93 Å to 3.03 Å, which doesn't react with the SOT and doesn't contain heavy metals. In some embodiments, the seed layer 202 may be a textured seed layer comprising an amorphous/crystalline migration layer and a seed layer combination, like NiFeTa/RuAl/NiFeGe, NiTa/NiFeGe, NiTa/NiFeGe/Ge, NiFeTa/RuAl/CuGe, NiTa/NiₓRu₍₁₋ₓ₎Al/NiGe, etc., (“/” denoting layer separation).

The first interlayer 206, the second interlayer 212, and the buffer layer 216 may each individually comprise NiₓRu₍₁₋ₓ₎Al (where x is from zero to 1) alloys, any crystalline or nanocrystalline, nonmagnetic element, or an alloy material with an equivalent BCC or B2 lattice parameter in the range of 2.93 Å to 3.03 Å, which doesn't react with the SOT and doesn't contain heavy metals. In some embodiments, the first interlayer 206, the second interlayer 212, and the buffer layer 216 may each individually comprise amorphous/crystalline layers or combinations of layers, such as Ge, NiFeGe, NiGe, CuGe, Ge/NiAl, Ge/RuAl, RuGe, MgO/Ge, MgO/NiFeGe, NiAlGe, or RuAlGe.

The cap layer 218 may comprise MgO, any material of the first interlayer 206, the second interlayer 212, or the buffer layer 216, an amorphous high resistant material, or layer combinations thereof, such as a multilayer stack of MgO and NiFeGe or other high resistance materials. The cap layer 218 may be a textured cap layer 218 comprising combination of high resistance crystalline or amorphous materials like TiO, TiN, MgO, composites like MgOTIO, NiFeGe, or Ge. The FM layer 208 may comprise bcc or Heusler FM materials, such as CoFe, CoFeMnGe, CoFeGe, CoFeAl, CoFeSi, etc.

In some embodiments, the first SOT layer 204 and the second SOT layer 214 each individually comprises a topological insulator material. The SOT layer 214 may comprise at least one of BiSb, a topological insulator, a topological half-Heusler alloy like YPtBi, and a weakly oxidized heavy metal. In some embodiments, the topological insulator material can be BiSb with (012) orientation to achieve the highest spin Hall angle (current-spin conversion efficiency). The BiSb material has been shown to have a giant spin Hall angle as large as 52 and an inverse spin Hall angle as large as 61, and thus can be applied to the first SOT layer 204 and the second SOT layer 214. Furthermore, the BiSb layer can be epitaxially grown by using an appropriate seed or interlayer, thus greatly reducing the variation of the switching current density for the FM layer on wafer scale. The first SOT layer 204 and the second SOT layer 214 is each individually disposed in contact with an appropriate buffer layer 216 and/or and interlayer 206, 212 to minimize diffusion and roughness. The first SOT layer 204 and the second SOT layer 214 may each individually comprise undoped BiSb or doped BiSbX, where the dopant is less than about 10 at. %, and where X is extracted from elements which don't readily interact with Bi, such as B, N, AI, Si, Ti, V, Ni, Cu, Ge, Y, Zr, Ru, Mo, Ag, Hf, W, Re, Ir, or in alloy combinations with one or more of aforementioned elements, like CuAg, CuNi, RuGe, etc. The benefit of the high spin Hall angle of the material of the first and second SOT layers 204, 214 is utilized for both writing and reading of the logic state or value encoded in the FM layer 208.

In some embodiments, the SO-SO device 250 comprises three terminals or interconnects. The first SOT layer 204 is coupled to an interconnect or terminal 1. The second SOT layer 214 is coupled to an interconnect or terminal 3, where the interconnect or terminal 3 is coupled to the first SOT layer 204 of a second SO-SO device via terminal 1. The arrows associated with the terminals indicate the direction of current flows, according to some embodiments. The interconnects or terminals serves as connection points for joining two or more SO-SO devices. Thus, multiple SO-SO devices 250-250 can be arranged to build out various circuits.

The SO-SO device is a hybrid device, utilizing both spin Hall effect (SHE) and inverse SHE (iSHE), and operates in a three-terminal configuration. In the context of the neural node described above, a SO-SO device can be used in one of two phases of DNN operations: a multiplication/summation phase and a non-linear transfer/activation phase. In addition, prior to, or during the multiplication/summation phase, the SO-SO device can be programmed to store a weight associated with a neural node. In one embodiment, terminal 1 receives a current representing the weight or control (e.g., W₁ . . . . Wₙ of FIG. 1B). The weight control (gate) current flows in-plane (current-in-plane (CIP)) of an SOT layer, such as the first SOT layer 204. This weight current in the SOT layer, due to the SHE, switches the FM layer 208's magnetization. When the weight control current is removed, the FM layer 208 stays in its current state and is nonvolatile. In a typical DNN implementation, the weights may be programmed or written as part of a training process (such as via a back propagation process), and the FM layer 208 of the SO-SO device for a neural node can thus be switched as part of the weight programming process. Or the weights may be programmed as part of the initialization of the SOT devices to ready them for DNN application. Then, during DNN execution, e.g., at inference, such weights encoded in the magnetization of the FM layer 208 are used as part of the multiplication/summation operation.

The multiplication portion of the multiplication/summation phase is performed as follows. An input current is applied to terminal 2 (representing an input Xₙ current to a neural node) and it flows out-of-plan (current-perpendicular-to-plane (CPP)) through the whole stack toward the seed layer 202. This current through the FM layer 208 becomes spin polarized and such spin current will inject into the second SOT layer 214, which, via the iSHE, there will be an electrical voltage induced in the second SOT layer 214 that is proportional to (1) the spin current magnitude or input current magnitude, and (2) FM layer 208's magnetization orientation previously driven by the SHE due to the current-in-plane (CIP) weight current coming in via terminal 1. Such voltage potential will generate a charge current output at terminal 3 if a load is connected. Terminal 3, the current output, is thus reflective of the magnetization of the FM layer 208 (the weight associated with the input to a neural node) and the magnitude of input CPP current (the input Xₙ to the neural node). By doing so, the multiplication function (weight times input) of the neural node in the DNN is performed by a hardware implementation. The SO-SO device uses the same spin-orbit coupling mechanism for both charge-to-spin and spin-to-charge conversion. Thus, the input stage (weight programming) and output stage (multiplication of weight and input during DNN operation such as during inference) can be stacked together, saving device footprint and increasing integration density.

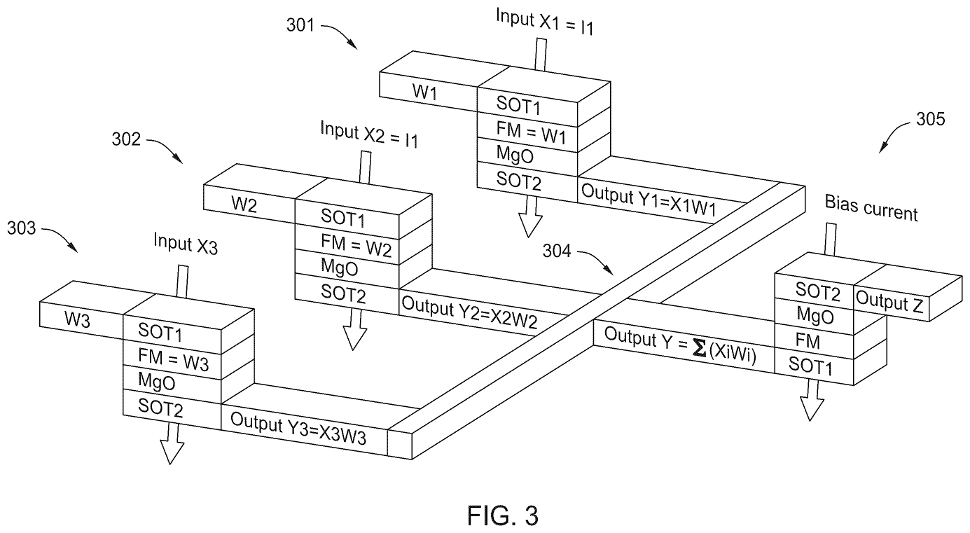

After the multiplication of the weight and input in a SO-SO device as described above, the outputs of multiple SO-SO devices, each performing a multiplication, can be joined (e.g., outputs of terminal 3 in the respective SO-SO devices coupled together). This joining achieves the summation operation in FIG. 1B, summing the collective X×W (inputs times weights) results. This is further shown in the example in FIG. 3 below. The result of the summation operation is then sent to the non-linear activation function phase.

During the non-linear activation function phase, an input current, representing the result of the summation, is applied to terminal 1 as a current-in-plane (CIP) current into the first SOT layer 204, inducing switching of the FM layer 208 via the generation of the SHE. A fixed supply current is applied to terminal 2 perpendicular through the SO-SO device 250, as a current-perpendicular-to-plane (CPP) into the second SOT layer 214. The current through the FM layer 208 becomes spin polarized and such spin current will inject into the second SOT layer 214 due to spin-accumulation, which, via the iSHE, there will be an electrical voltage induced in the second SOT layer 214 that is proportional to the spin current magnitude. Such voltage potential will generate a charge current which forms the current output at terminal 3 if a load is connected. Terminal 3, the current output, is thus reflective of the magnetization of the FM layer 208 which is governed by an input current at terminal 1, and hence implementation of the transfer function of input current, which is intrinsically non-linear in nature.

As noted above, in the non-linear function phase, the SO-SO device 250 is configured for a first current path that is in plane to a plane of the first SOT layer 204, and a second current path that is perpendicular to a plane of the second SOT layer 214, the second current path being configured to extend into the FM layer 208. In some embodiments, the second current path is configured to further extend into the first SOT layer 204 as well. For example, the SO-SO device 250 is configured to receive an input current at the first current path, and the first SOT layer 204 is configured to affect a direction of a magnetization of the FM layer 208 due to the input current. SO-SO device 250 is configured to receive a supply current (I_{supply}) at the second current path, and to generate, via the second SOT layer 214, an output current (Iₒᵤₜₚᵤₜ) responsive to a direction of the magnetization of the FM layer 208. The output current exits at terminal 3.

FIG. 3 shows SO-SO devices configured to perform a MAC operation and a non-linear activation function operation of a neural node, according to one embodiment. In this example, each of SO-SO devices 301-303 can be fabricated and configured as described previously in FIG. 2. Here, the input bias currents I₁₋ₙ (corresponding to terminal 2 in FIG. 2) represent neural network input X₁₋ₙ in FIG. 1B, i.e., the input values into the neural node. The magnetization states in the FM layers of the SO-SO devices 301-303 encode the neural network weights (W₁₋ₙ in FIG. 1B). The magnetization (M) states can be either +M (positive), −M (negative), or an arbitrary analog value in between, depending on the domain wall position in the FM layer. In some embodiments, the magnetization states can be controlled by the setting current pulse width or amplitude via the input current labeled as Control₁₋ₙ (corresponding to terminal 1 in FIG. 2, W1-W3 here in FIG. 3). As described above, in some embodiments, the weights are programmed in the FM layers prior to the multiplication. In this manner, each SO-SO device 301-303 performs the logic multiplication operation of an input Xₙ times a weight Wₙ. As further shown, the results of the devices 301-303 (Y₁₋ₙ) are then summed at the interconnect junction 304. Thus, the total output current is Y=Σ(XᵢWᵢ), representing the MAC operation shown in FIG. 1B. In this manner, the SO-SO devices can be configured together to perform the MAC operation. The SO-SO devices 301-303 and the interconnect junction 304 represent the multiplication/summation phase.

FIG. 3 further shows a SO-SO device configured to perform the activation function of a neural node, according to one embodiment. The figure shows the summed total output current Y=Σ(XᵢWᵢ) being fed to an output SO-SO device 305, which in one embodiment has an abrupt threshold current density for switching of its FM layer. This can be realized by reducing the size of the FM layer of the SO-SO device 305 so that the magnetization switching mechanism is coherent switching. Thus, this output SO-SO device 305 works logically as a step-like transfer function. The SO-SO device 305 is reversed compared to the SO-SO devices 301-303, such that the total output current Y=Σ(XᵢWᵢ) is input into the SOT1 layer of the SO-SO device 305. The SO-SO device 305 represents the non-linear function phase. It is noted that in some embodiments, SO-SO device 305 may be replaced by other analog circuitry capable of performing the non-linear transfer function, such as a circuit implementing a ReLU function.

In addition, the bias current of the output SO-SO device 305 can be set so that the output Z can be high enough to drive the next stage. This final output Z then can be fetched to the next neural node layer(s). In this manner, a SO-SO device can be configured to perform the activation function operation. FIG. 3 shows how multiple SO-SO devices can be configured to perform the functions of a neural node in a neural network, such as the DNN 100 of FIG. 1A.

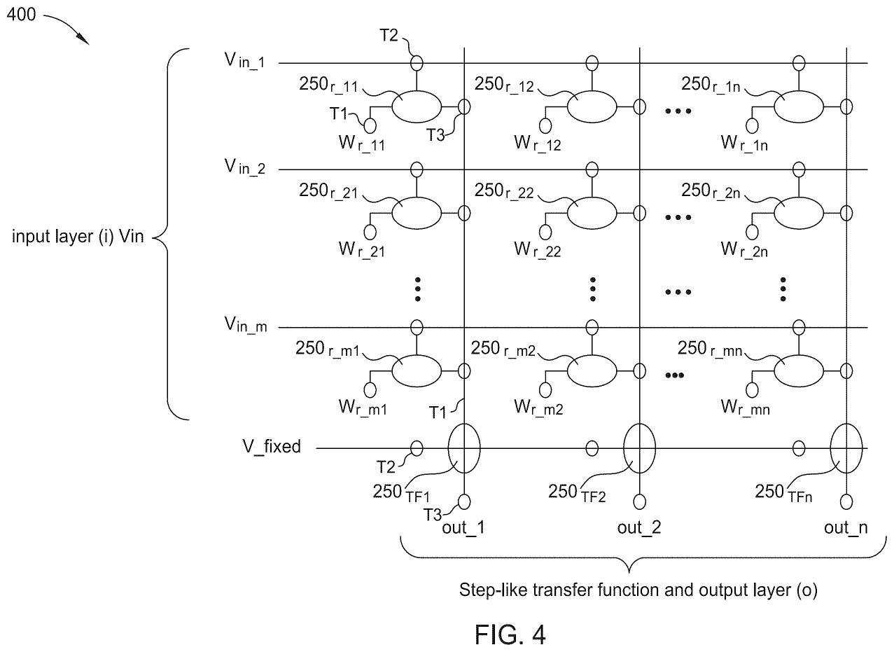

FIG. 4 illustrates a cross-bar array 400 type of implementation for a DNN, according to one embodiment. The cross-bar array 400 may be a part of the DNN 100 of FIG. 1A. A DNN may comprise a plurality of cross-bar arrays 400. In the cross-bar array 400, a SO-SO device 250 is disposed at each cross-point. While three rows (r_1, r_2, r_n) and three columns (r_(x)1, r_(x)2, r_(x)m, where x designates the row number) are shown in the array 400, the array 400 may comprise any number of rows and columns. In the MAC SO-SO device, terminal 1 (T1) is the weight input, terminal w (T2) is the Vin input, and terminal 3 (T3) is tied to the column summation circuit line. In the activation SO-SO device, T1 is the column summation circuit line, T2 is V_fixed, and T3 in the output.

In the cross-bar array 400, each column represents a neural mode discussed above where multiple SO-SO devices are used to perform the weight times input multiplication operations, the sum of which (the summation step) is generated by tying the outputs into the corresponding column circuit line. The sum is then sent to a SO-SO (250_{TFn}) at the bottom of the column for the activation function operation. Specifically, a first input current or voltage (V_{in_1}) is input to a first row of SO-SO devices 250, where the first SO-SO device 250_{r_11} has a weight (W) of W_{r_11}, the second SO-SO device 250_{r_12} has a weight of W_{r_12}, and the last SO-SO device 250_{r_in} has a weight of W_{r_in}. Similarly, a second current or voltage (V_{in_2}) is input to a second row of SO-SO devices 250, where the first SO-SO device 250_{r_21} has a weight of W_{r_21}, the second SO-SO device 250_{r_22} has a weight of W_{r_22}, and the last SO-SO device 250_{r_2n} has a weight of W_{r_2n}. A third (or last) current or voltage (V_{in_m}) is input to a third (or last) row of SO-SO devices 250, where the first SO-SO device 250_{r_m1} has a weight of W_{r_m1}, the second SO-SO device 250_{r_m2} has a weight of W_{r_m2}, and the last SO-SO device 250_{r_mn} has a weight of W_{r_mn}. As described above, the weights of each device may be programmed via the SHE prior to the performance of the multiplication and summation operation.

The input current or voltage of each row is then multiplied by each weight of the SO-SO devices 250 within the row. The output of each SO-SO device 250 within each column is then fed into a common SO-SO (SO-SO device 250_{TF1} for column 1, SO-SO device 250_{TF2} for column 2, and SO-SO device 250_{TFn} for column n) for the activation function, which then becomes the final outputs (out_1, out_2, out_n). Each output out_1, out_2, out_n may then be used as the input for the next layer within the DNN, like described above in FIG. 1A, where the voltage (V_fixed) is a bias current. For example, the output out_1, out_2, out_n may be fed as input V_{in_1-m} for another portion of the array (or another array) used to represent the next layer of neural nodes. Alternatively, in some embodiments, the SO-SO devices within cross-bar array 400 can be reprogrammed with weights associated with the neural nodes of the next layer, and the output can be fed back as input V_{in_1-m} after the weight has been programmed.

Thus, by utilizing a SO-SO device comprising a plurality of SO-SO devices, each SO-SO device comprising a first SOT layer and a second SOT layer, the SO-SO device effectively functions as a building block for a DNN capable of performing logic and Al operations while reducing energy consumption. Furthermore, the simplified structure of the SO-SO device has scaling advantages while maintaining a low energy consumption, making the SO-SO device mass-production friendly while easy to bias.

In one embodiment, a DNN device comprises one or more first devices configured to perform a first operation of a neural node of a deep neural network (DNN), the one or more first devices each comprising: a first spin orbit torque (SOT1) layer, a second spin orbit torque (SOT2) layer, a ferromagnetic layer disposed between the SOT1 and SOT2 layer, a first terminal coupled to the SOT1 layer, a second terminal coupled over the SOT2 layer, the second terminal being configured for an input current path that is perpendicular to a plane of the SOT2 layer, the input current path being configured to extend into the ferromagnetic layer, and a third terminal coupled to the SOT2 layer, the third terminal being configured for an output current path that is in plane of the SOT2 layer.

The SOT1 layer is configured to affect a direction of a magnetization of the ferromagnetic layer based on a weight current received at the first terminal. Each of the one or more first devices is further configured to receive an input current at the input current path, and output an output based on the affected direction of magnetization of the ferromagnetic layer. The DNN device further comprises one or more second devices configured to perform a second operation of a neural node of a DNN, the one or more second devices each comprising: a second SOT1 layer, a second SOT2 layer, a second ferromagnetic layer disposed between the second SOT1 and second SOT2 layer, a first terminal coupled to the second SOT1 layer, the first terminal being configured for an input current path that is in plane to a plane of the second SOT1 layer, a second terminal coupled over the second SOT2 layer, the second terminal being configured for a supply current path that is perpendicular to a plane of the second SOT2 layer, the supply current path being configured to extend into the ferromagnetic layer, and a third terminal coupled to the second SOT2 layer, the third terminal being configured for an output current path that is in plane of the second SOT2 layer. The SOT1 layer and the SOT2 layer each individually comprises YPtBi.

The output current of one or more first cells is input as an input current into one or more second devices. The output current of the one or more first devices are summed together prior to being input into the one or more second devices. Each of the first devices further comprises an oxide layer disposed between the ferromagnetic layer and the SOT2 layer. The SOT1 layer and the SOT2 layer each individually comprises doped or undoped BiSb. The DNN device further comprises one or more interlayer between the SOT1 layer and the SOT2 layer, the interlayer comprising one or more of Ni, Ru, Al, Ge, Fe, Cu, Ge, MgO, and combinations thereof.

In another embodiment, a DNN device comprises a plurality of rows, a plurality of columns, a SO-SO device disposed at each cross-point between rows of the plurality of rows and columns of the plurality of columns configured to perform a first operation of a neural node of a deep neural network (DNN), each SO-SO device comprising: a first spin orbit torque (SOT1) layer, a second spin orbit torque (SOT2) layer, and a ferromagnetic layer disposed between the SOT1 and SOT2 layer, wherein a plurality of input currents are configured to be applied to each SO-SO device disposed in each row of the plurality of rows, and a plurality of output SO-SO devices disposed within each column configured to perform a second operation of a neural node of a DNN, each output SO-SO comprising: a SOT1 layer, a SOT2 layer, and a ferromagnetic layer disposed between the SOT1 and SOT2 layer, wherein an output current of each SO-SO device disposed in each column of the plurality of columns is configured to be input as an input current into the plurality of output SO-SO devices.

Each SO-SO device and each output SO-SO device further comprises an oxide layer disposed between the ferromagnetic layer and the SOT2 layer. The SOT1 layer and the SOT2 layer of each SO-SO device and each output SO-SO device each individually comprises doped or undoped BiSb. The SOT1 layer of each SO-SO device is configured to affect a direction of a magnetization of the ferromagnetic layer based on a weight current received at the first terminal. Each SO-SO device is further configured to receive an input current at the input current path, and output an output based on the affected direction of magnetization of the ferromagnetic layer. Each SO-SO device is further configured to generate, via the SOT2 layer, the output current responsive to a direction of the magnetization of the ferromagnetic layer and the input current. The SOT1 layer and the SOT2 layer of each SO-SO device and each output SO-SO device each individually has a (012) orientation. The SOT1 layer and the SOT2 layer of each SO-SO device and each output SO-SO device each individually comprises YPtBi. The first operation is a multiply function of a multiply and accumulate (MAC) operation, and wherein the second operation is an activation function.

In yet another embodiment, a DNN device comprises a first layer of a plurality of first spin orbit torque (SOT) devices configured to perform a first operation of a neural node of a deep neural network (DNN), each first SOT device comprising: a first spin orbit torque layer, a second spin orbit torque layer coupled to a first output terminal, and a ferromagnetic layer disposed between the first and second spin orbit torque layers, wherein each first SOT device is individually configured to generate, via the second SOT layer, an output current responsive to a direction of the magnetization of the ferromagnetic layer and the input current, the output current being output through the first output terminal of each first SOT device, and a second layer of a plurality of second SOT devices configured to perform a second operation of a neural node of a DNN, each second SOT device comprising: a first spin orbit torque layer coupled to a first input terminal, a second spin orbit torque layer, and a ferromagnetic layer disposed between the first and second spin orbit torque layers, wherein the output current of each first SOT device is configured to be input into the first input terminal of each second SOT device.

Each first SOT device further comprises an oxide layer disposed between the ferromagnetic layer and the second spin orbital torque layer, and wherein each second SOT device further comprises an oxide layer disposed between the ferromagnetic layer and the second spin orbital torque layer. The output currents of each first SOT device are summed together prior to being input into the first input terminal of each second SOT device. Each first SOT device further comprises a second input terminal configured to receive an input current, and wherein the input current is directed perpendicularly into the second SOT layer. The first spin orbit torque layer of each first SOT device is configured to affect a direction of a magnetization of the ferromagnetic layer based on a weight current received at the first terminal. The first operation is a multiply function of a multiply and accumulate (MAC) operation, and wherein the second operation is an activation function. The first orbit torque layer and the second orbit torque layer of each first SOT device and of each second SOT devices individually comprises BiSb. The BiSb has a (012) orientation. The first orbit torque layer and the second orbit torque layer of each first SOT device and of each second SOT devices individually comprises YPtBi.

While the foregoing is directed to embodiments of the present disclosure, other and further embodiments of the disclosure may be devised without departing from the basic scope thereof, and the scope thereof is determined by the claims that follow.

What is claimed is:

1. A deep neural network (DNN) device, the DNN device comprising:
one or more first devices configured to perform a first operation of a neural node of a deep neural network (DNN), the one or more first devices each comprising:
a first spin orbit torque (SOT1) layer;
a second spin orbit torque (SOT2) layer;
a ferromagnetic layer disposed between the SOT1 and SOT2 layer;
a first terminal coupled to the SOT1 layer;
a second terminal coupled over the SOT2 layer, the second terminal being configured for an input current path that is perpendicular to a plane of the SOT2 layer, the input current path being configured to extend into the ferromagnetic layer; and
a third terminal coupled to the SOT2 layer, the third terminal being configured for an output current path that is in plane of the SOT2 layer.

2. The DNN device of claim 1, wherein the SOT1 layer is configured to affect a direction of a magnetization of the ferromagnetic layer based on a weight current received at the first terminal.

3. The DNN device of claim 2, wherein each of the one or more first devices is further configured to receive an input current at the input current path, and output an output based on the affected direction of magnetization of the ferromagnetic layer.

4. The DNN device of claim 1, further comprising:
one or more second devices configured to perform a second operation of a neural node of a DNN, the one or more second devices each comprising:
a second SOT1 layer;
a second SOT2 layer;
a second ferromagnetic layer disposed between the second SOT1 and second SOT2 layer;
a first terminal coupled to the second SOT1 layer, the first terminal being configured for an input current path that is in plane to a plane of the second SOT1 layer;
a second terminal coupled over the second SOT2 layer, the second terminal being configured for a supply current path that is perpendicular to a plane of the second SOT2 layer, the supply current path being configured to extend into the ferromagnetic layer; and
a third terminal coupled to the second SOT2 layer, the third terminal being configured for an output current path that is in plane of the second SOT2 layer.

5. The DNN device of claim 4, wherein the output current of the one or more first devices is input as an input current into the one or more second devices.

6. The DNN device of claim 5, wherein the output current of the one or more first devices are summed together prior to being input into the one or more second devices.

7. The DNN device of claim 1, wherein each of the first devices further comprises an oxide layer disposed between the ferromagnetic layer and the SOT2 layer.

8. The DNN device of claim 1, wherein the SOT1 layer and the SOT2 layer each individually comprises doped or undoped BiSb.

9. The DNN device of claim 1, wherein the SOT1 layer and the SOT2 layer each individually comprises doped or undoped YPtBi.

10. The DNN device of claim 1, further comprising one or more interlayer between the SOT1 layer and the SOT2 layer, the interlayer comprising one or more of Ni, Ru, Al, Ge, Fe, Cu, Ge, MgO, and combinations thereof.

11. A deep neural network (DNN) device, the DNN device comprising:
a plurality of rows;
a plurality of columns;
a spin-orbit spin-orbit (SO-SO) device disposed at each cross-point between rows of the plurality of rows and columns of the plurality of columns configured to perform a first operation of a neural node of a deep neural network (DNN), each SO-SO device comprising:
a first spin orbit torque (SOT1) layer;
a second spin orbit torque (SOT2) layer; and
a ferromagnetic layer disposed between the SOT1 and SOT2 layer, wherein a plurality of input currents are configured to be applied to each SO-SO device disposed in each row of the plurality of rows; and
a plurality of output SO-SO devices disposed within each column configured to perform a second operation of a neural node of a deep neural network (DNN), each output SO-SO device comprising:
a SOT1 layer;
a SOT2 layer; and
a ferromagnetic layer disposed between the SOT1 and SOT2 layer, wherein an output current of each SO-SO device disposed in each column of the plurality of columns is configured to be input as an input current into the plurality of output SO-SO devices.

12. The DNN device of claim 11, wherein each SO-SO device and each output SO-SO device further comprises an oxide layer disposed between the ferromagnetic layer and the SOT2 layer.

13. The DNN device of claim 11, wherein the SOT1 layer and the SOT2 layer of each SO-SO device and each output SO-SO device each individually comprises doped or undoped BiSb.

14. The DNN device of claim 11, wherein the SOT1 layer of each SO-SO device is configured to affect a direction of a magnetization of the ferromagnetic layer based on a weight current received at the first terminal.

15. The DNN device of claim 14, wherein each SO-SO device is further configured to receive an input current at the input current path, and output an output based on the affected direction of magnetization of the ferromagnetic layer.

16. The DNN device of claim 11, wherein each SO-SO device is further configured to generate, via the SOT2 layer, the output current responsive to a direction of the magnetization of the ferromagnetic layer and the input current.

17. The DNN device of claim 11, wherein the SOT1 layer and the SOT2 layer of each SO-SO device and each output SO-SO device each individually has a (012) orientation.

18. The DNN device of claim 11, wherein the SOT1 layer and the SOT2 layer of each SO-SO device and each output SO-SO device each individually comprises YPtBi.

19. The DNN device of claim 11, wherein the first operation is a multiply function of a multiply and accumulate (MAC) operation, and wherein the second operation is an activation function.

20. A deep neural network (DNN) device, the DNN device comprising:
a first layer of a plurality of first spin orbit torque (SOT) devices configured to perform a first operation of a neural node of a deep neural network (DNN), each first SOT device comprising:
a first spin orbit torque layer;
a second spin orbit torque layer coupled to a first output terminal; and
a ferromagnetic layer disposed between the first and second spin orbit torque layers,
wherein each first SOT device is individually configured to generate, via the second SOT layer, an output current responsive to a direction of the magnetization of the ferromagnetic layer and an input current, the output current being output through the first output terminal of each first SOT device; and
a second layer of a plurality of second SOT devices configured to perform a second operation of a neural node of a deep neural network (DNN), each second SOT device comprising:
a first spin orbit torque layer coupled to a first input terminal;
a second spin orbit torque layer; and
a ferromagnetic layer disposed between the first and second spin orbit torque layers,
wherein the output current of each first SOT device is configured to be input into the first input terminal of each second SOT device.

21. The DNN device of claim 20, wherein each first SOT device further comprises an oxide layer disposed between the ferromagnetic layer and the second spin orbital torque layer, and wherein each second SOT device further comprises an oxide layer disposed between the ferromagnetic layer and the second spin orbital torque layer.

22. The DNN device of claim 20, wherein the output currents of each first SOT device are summed together prior to being input into the first input terminal of each second SOT device.

23. The DNN device of claim 20, wherein each first SOT device further comprises a second input terminal configured to receive the input current, and wherein the input current is directed perpendicularly into the second SOT layer.

24. The DNN device of claim 23, wherein the first spin orbit torque layer of each first SOT device is configured to affect a direction of a magnetization of the ferromagnetic layer based on a weight current received at the first terminal.

25. The DNN device of claim 20, wherein the first operation is a multiply function of a multiply and accumulate (MAC) operation, and wherein the second operation is an activation function.

26. The DNN device of claim 20, wherein the first orbit torque layer and the second orbit torque layer of each first SOT device and of each second SOT devices individually comprises BiSb.

27. The DNN device of claim 26, wherein the BiSb has a (012) orientation.

28. The DNN device of claim 20, wherein the first orbit torque layer and the second orbit torque layer of each first SOT device and of each second SOT devices individually comprises YPtBi.
